(19) United States
(12) Patent Application Publication
(10) Pub. No.: US 2007/0284702 A1
(43) Pub. Date: Dec. 13, 2007

(54) Semiconductor device having a bonding pad and fuse and method for forming the same

(76) Inventor: Gyong-Sub Im, Paldal-gu (KR)

Correspondence Address: LEE & MORSE, P.C., 3141 FAIRVIEW PARK DRIVE, SUITE 500, FALLS CHURCH, VA, 22042, US

(21) Appl. No.: 11/790,588

(22) Filed: Apr. 26, 2007

(30) Foreign Application Priority Data
May 10, 2006 (KR) 2006-42072

(51) Int. Cl. H01L 21/44; H01L 23/58

(52) U.S. Cl. 257/649; 438/612; 257/E21.085

(57) ABSTRACT

A semiconductor device, including an interlayer dielectric layer having a bonding pad and a fuse on a semiconductor substrate, the interlayer dielectric layer having a pad opening and a fuse opening exposing the bonding pad and the fuse, an organic passivation layer on the interlayer dielectric layer, and a fuse passivation layer covering the organic passivation layer, a side surface of the pad opening, a side surface of the fuse opening, and a bottom surface of the fuse opening.

### BACKGROUND OF THE INVENTION

1. Field of the Invention

The present invention relates to a semiconductor device. More particularly, the present invention relates to a semiconductor device including a bonding pad and a fuse, and a method for forming the same.

2. Description of the Related Art

A semiconductor device may include multiple unit devices formed on a substrate along with wires electrically connected to the unit devices according to a design lay-out. Generally, a semiconductor device may have pads for inputting or outputting power and electric signals in order to perform a proper function. A fuse may convert a module or a unit device on the basis of an electrical test to evaluate defects of a preliminary circuit.

FIG. 1 illustrates a cross-sectional view of a general semiconductor device. Referring to FIG. 1, an interlayer dielectric layer 50 having a fuse 20 and a bonding pad 40 may be on a semiconductor substrate 10. An organic passivation layer 60 may be on the interlayer dielectric layer 50. A pad opening 63 may be on the bonding pad 40, and a fuse opening 66 may be on the fuse 20. In the general semiconductor device, the fuse 20 and the organic passivation layer 60 may be exposed. This exposure may cause problems which are discussed below.

First, because the fuse 20 is exposed, particles may be generated by the cutting of a fuse bridge to generate a short between fuses. Also, the fuse 20 may be corroded by the infiltration of moisture.

Second, before the wafer processing is completed by performing die separation, i.e., die singulation, a backgrind to reduce a thickness of the wafer may be performed. At this time, a tape may be attached to the front side of the wafer to protect the semiconductor device from particle contamination. When the tape is removed after finishing the backgrind, the fuse 20 and/or the organic passivation layer 60 may be removed together. Especially, since an upper surface of the organic passivation layer 60 goes through various processes that may damage the surface, the damaged surface may enhance adhesive strength with the tape to increase the probability that the organic passivation layer may be removed with the tape.

These problems may thus reduce the reliability and a yield of semiconductor devices.

The above information disclosed in this Background section is only for enhancement of understanding of the background of the invention, and therefore it may contain information that does not form the prior art that is already known in this country to a person of ordinary skill in the art.

### SUMMARY OF THE INVENTION

The present invention is therefore directed to a semiconductor device and method of forming the same, which substantially overcomes one or more of the problems due to the limitations and disadvantages of the related art.

It is therefore a feature of an embodiment of the present invention to provide a semiconductor device having an interlayer dielectric layer having a bonding pad and a fuse, and a method of forming the same.

At least one of the above and other features and advantages of the present invention may be realized by providing a method of forming a semiconductor device which may include forming an interlayer dielectric layer including a bonding pad and a fuse on a semiconductor substrate, forming an organic passivation layer on a predetermined region of the interlayer dielectric layer, forming a pad opening and a fuse opening exposing the bonding pad and the fuse by patterning the interlayer dielectric layer by etching using the organic passivation layer as an etch mask to expose the bonding pad and the fuse, forming a fuse passivation layer covering the semiconductor substrate, and patterning the fuse passivation layer to expose the bonding pad.

The fuse passivation layer may cover a side surface of the pad opening, and the fuse. The fuse passivation layer may conform to a profile of the semiconductor substrate. The fuse passivation layer may be composed of at least one of silicon oxide layer or a silicon nitride layer. The organic passivation layer may be composed of photosensitive polyimide.

At least one of the above and other features and advantages of the present invention may be realized by providing a method of forming a semiconductor device which may include forming a first interlayer dielectric layer including a fuse on a semiconductor substrate, forming a second interlayer dielectric layer including a bonding pad on the first interlayer dielectric layer, forming an organic passivation layer on a predetermined region of the second interlayer dielectric layer, forming a pad opening and a fuse opening exposing the bonding pad and the fuse by patterning the first and the second interlayer dielectric layers by etching using the organic passivation layer as an etch mask, forming a fuse passivation layer covering the organic passivation layer, a side surface and a bottom surface of the pad opening, and the fuse opening, and patterning the fuse passivation layer to expose the bonding pad.

At least one of the above and other features and advantages of the present invention may be realized by providing a semiconductor device including an interlayer dielectric layer having a bonding pad and a fuse on a semiconductor substrate, the interlayer dielectric layer having a pad opening and a fuse opening exposing the bonding pad and the fuse, respectively, an organic passivation layer on the interlayer dielectric layer, and a fuse passivation layer covering the organic passivation layer and exposing the bonding pad.

The organic passivation layer may be composed of photosensitive polyimide. The fuse passivation layer may be composed of at least one of a silicon oxide layer or a silicon nitride layer. The fuse passivation layer may cover a side surface of the pad opening, a side surface of the fuse opening, and a bottom surface of the fuse opening. The fuse and the bonding pad may be composed of aluminum or copper. The organic passivation layer may shield the semiconductor device from alpha particles. The interlayer dielectric layer may be composed of a first interlayer dielectric layer including the fuse and a second interlayer dielectric layer including the bonding pad. The second interlayer dielectric layer may be composed of a bottom oxide layer and an upper nitride layer, and the bottom oxide layer surrounds the bonding pad. The first and the second interlayer dielectric layers may each be composed of at least one of tetraethyl orthosilicate, high density plasma oxide, borophosphosilicate glass, borosilicate glass, or phosphosilicate glass. An upper surface of the first interlayer dielectric layer may be higher than an upper surface of the fuse. An upper surface of the second interlayer dielectric layer may be higher than an upper surface of the bonding pad.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a cross-sectional view of a general semiconductor device;

FIG. 2 illustrates a cross-sectional view illustrating a semiconductor device according to an embodiment of the present invention;

FIGS. 3 to 8 illustrate cross-sectional views of stages of a method of forming a semiconductor device according to an embodiment of the present invention; and

FIG. 9 illustrates a flowchart explaining a method of forming a semiconductor device according to an embodiment of the present invention.

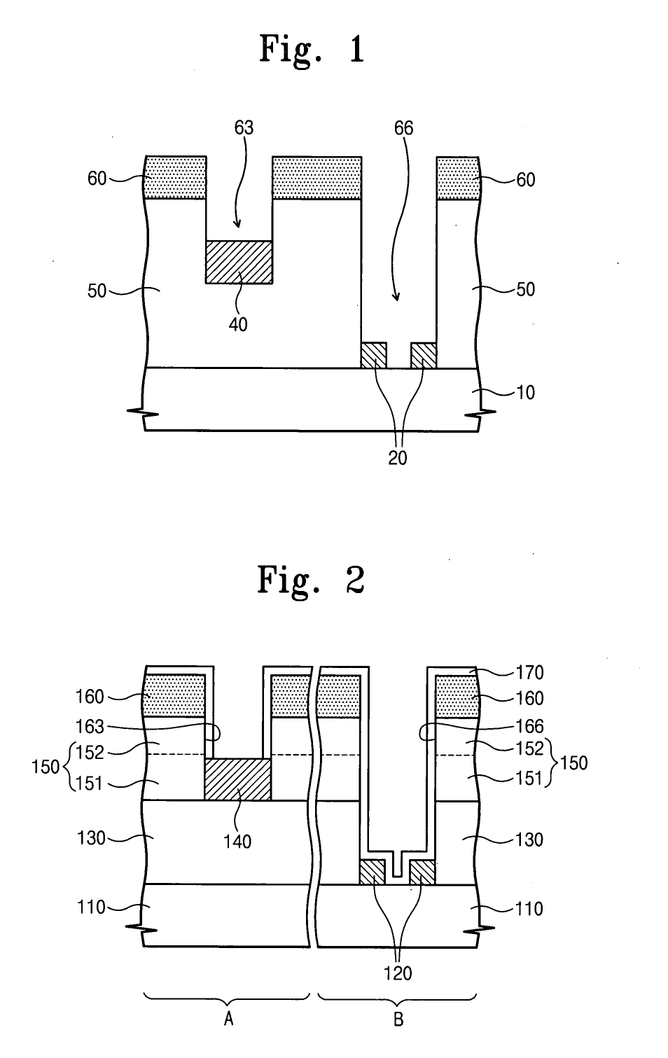

### DETAILED DESCRIPTION OF THE INVENTION

Korean Patent Application 2006-42072 filed on May 10, 2006, in the Korean Intellectual Property Office, and entitled: “Semiconductor Device and Method for Forming the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

FIG. 2 illustrates a cross-sectional view of a semiconductor device according to an embodiment of the present invention.

Referring to FIG. 2, a semiconductor substrate 110 may include a pad region A and a fuse region B. The semiconductor substrate 110 may include an active device, a passive device, and an insulation layer covering the active and the passive devices (not shown).

First and second interlayer dielectric layers 130 and 150 including a fuse 120 and a bonding pad 140 may be located on the semiconductor substrate 110. The interlayer dielectric layers may include the first interlayer dielectric layer 130 surrounding the fuse 120 and the second interlayer dielectric layer 150 surrounding the bonding pad 140. The second interlayer dielectric layer 150 may be on the first interlayer dielectric layer 130. The first and second interlayer dielectric layers 130 and 150 may each include at least one of, e.g., a tetraethyl orthosilicate (TEOS) layer, a high density plasma (HDP) oxide layer, a borophosphosilicate glass (BPSG) layer, a borosilicate glass (BSG) layer, a phosphosilicate glass (PSG) layer, etc.

An upper surface of the first interlayer dielectric layer 130 may be higher than an upper surface of the fuse 120, and an upper surface of the second interlayer dielectric layer 150 may be higher than an upper surface of the bonding pad 140. The second interlayer dielectric layer 150 may include a bottom oxide layer 151 and an upper nitride layer 152. The bottom oxide layer 151 may surround the bonding pad 140, and an upper surface of the bottom oxide layer 151 may be higher than an upper surface of the bonding pad 140.

An organic passivation layer 160 may be located on the second interlayer dielectric layer 150. The organic passivation layer 160 may be formed of photosensitive polyimide (PSPI). The organic passivation layer 160 may be used as an etch mask during an etch process of forming a pad opening and a fuse opening, and to stabilize a device property by protecting a surface of the semiconductor device from outside influences and the environment. That is, the organic passivation layer 160 may prevent soft errors generated by an infiltration, e.g., a penetration of alpha particles, into the semiconductor device.

The fuse 120 may replace a bad cell detected during an electrical test of a semiconductor chip with a redundancy cell. That is, replacing a bad cell with a redundancy cell may be performed by a fuse repair by cutting the fuse. Various methods may be used to cut the fuse. Generally, using a laser to cut the fuse is simple and definite, and this technique is widely used.

The bonding pad 140 may be electrically connected to wires located in a lower part of the semiconductor device. Semiconductor devices (not shown) on the semiconductor substrate 110 may be electrically connected to an outer terminal through the bonding pad 140. The bonding pad 140 may be connected to the outer terminal by a conductive wire or a solder ball. A separate conductive pad filling the pad opening 163 may be arranged on the bonding pad 140. In this case, the bonding pad 140 may include the conductive pad. The bonding pad 140 may also be called an input-output pad, because input-output signals between the semiconductor device and the outer terminal are transmitted through the bonding pad 140.

The fuse 120 and the bonding pad 140 may include a barrier metal layer or an anti reflection coating (ARC) in or on an upper and/or a lower part.

A pad opening 163 and a fuse opening 166 may be located on the bonding pad 140 and the fuse 120. The pad opening 163 may penetrate the second interlayer dielectric layer 150 and the organic passivation layer 160 to expose the bonding pad 140, and the fuse opening 166 may penetrate the first and the second interlayer dielectric layers 130, 150 and the organic passivation layer 160 to expose the fuse 120.

A fuse passivation layer 170 may be located on the semiconductor substrate 110. The fuse passivation layer 170 may include at least one of a silicon oxide layer and/or a silicon nitride layer. The fuse passivation layer 170 may cover a side of the pad opening 163, a side and a bottom surface of the fuse opening 166, and an upper surface of the organic passivation layer 160. The fuse passivation layer 170 may expose the bonding pad 140. The fuse 120 and the organic passivation layer 160 may be protected from outside influences, e.g., alpha particles, by the fuse passivation layer 170. The fuse passivation layer 170 may prevent the fuse 120 from corroding by the infiltration of moisture and from forming a short by particles generated by cutting of the fuse. When a tape attached on the wafer to protect the semiconductor device from particles generated during the backgrind process is removed, the fuse and the organic passivation layer may be prevented from being removed.

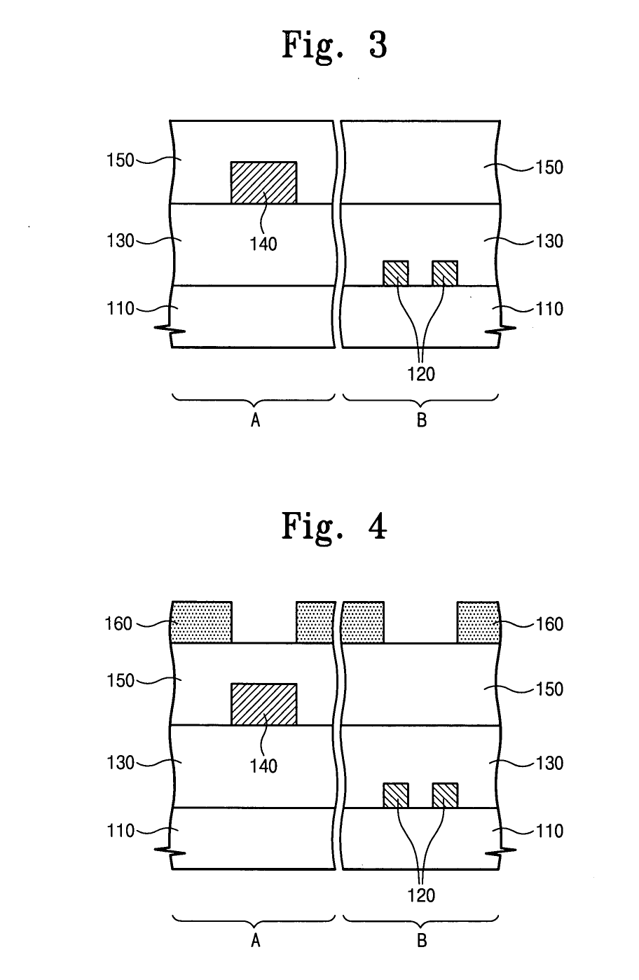

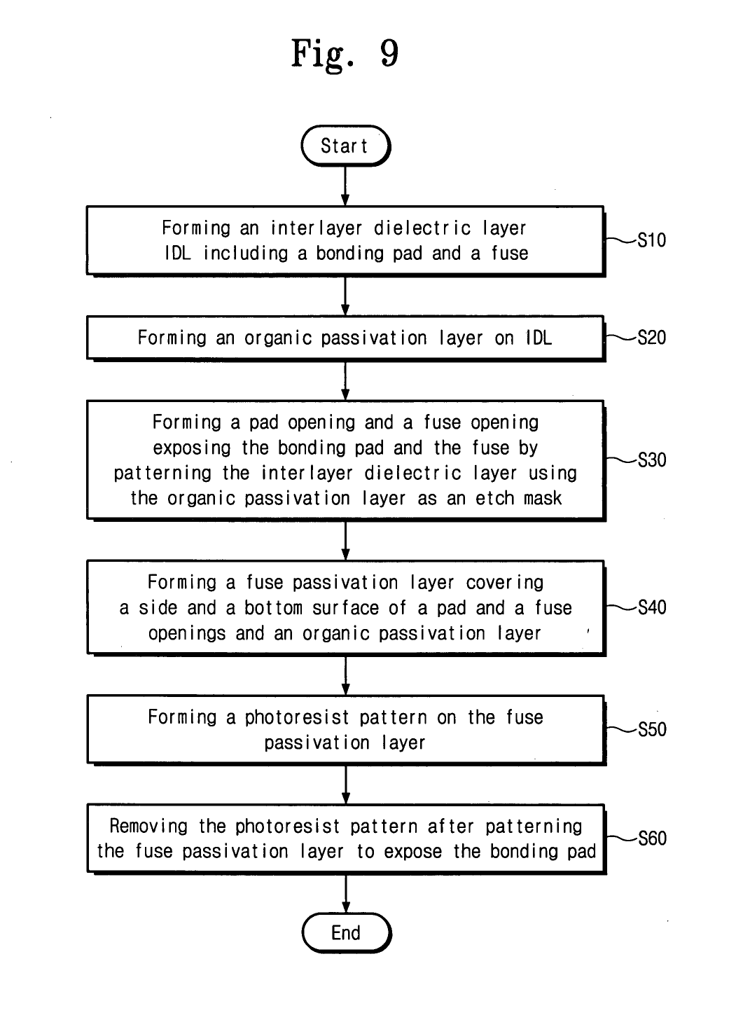

FIGS. 3 to 8 illustrate cross-sectional views of stages of a method of forming a semiconductor device according to an embodiment of the present invention. FIG. 9 illustrates a flowchart of a method of forming a semiconductor device according to an embodiment of the present invention.

Referring to FIG. 3 and FIG. 9, a first interlayer dielectric layer 130 including a fuse 120 and a second interlayer dielectric layer 150 including a bonding pad 140 may be formed on a semiconductor substrate 110 including a pad region A and a fuse region B (S10). The semiconductor substrate 110 may include a passive device, an active device, and an insulation layer covering the passive device and the active device (not shown). The first interlayer dielectric layer 130 and the second interlayer dielectric layer 150 may be formed to cover the fuse 120 and the bonding pad 140, respectively. The second interlayer dielectric layer 150 may be deposited on the first interlayer dielectric layer 130. The first and the second interlayer dielectric layers 130, 150 may each be formed of at least one of, e.g., a TEOS layer, a HDP oxide layer, a BPSG layer, a BSG layer, a PSG layer, etc. A bottom part of the second interlayer dielectric layer 150 may be formed of an oxide layer, and an upper part thereof may be formed of a nitride layer.

The fuse 120 may be formed in the fuse region B, and the bonding pad 140 may be formed in the pad region A. Although not illustrated, the bonding pad 140 may be electrically connected to wires formed in a lower part. The fuse 120 and the bonding pad 140 may be formed of a conductive material such as a metal, e.g., aluminum, copper, etc. A barrier metal layer or an ARC layer may be formed in or on an upper part and/or a lower part of the fuse 120 and the bonding pad 140.

Referring to FIG. 4 and FIG. 9, an organic passivation layer 160 may be formed on a predetermined region of the second interlayer dielectric layer 150 (S20). The organic passivation layer 160 may be formed of, e.g., photosensitive polyimide. After forming a photosensitive polyimide layer on the semiconductor substrate, the organic passivation layer 160 may be formed by a light exposure and developing processes.

Referring to FIG. 5 and FIG. 9, an etch process may be performed to form a pad opening 163 exposing the bonding pad 140 and a fuse opening 166 exposing the fuse 120 (S30). In the etch process, the organic passivation layer 160 may be used as an etch mask. As a result, a single process may be more simple than processes of forming the openings 163 and 166 and the organic passivation layer 160 separately.

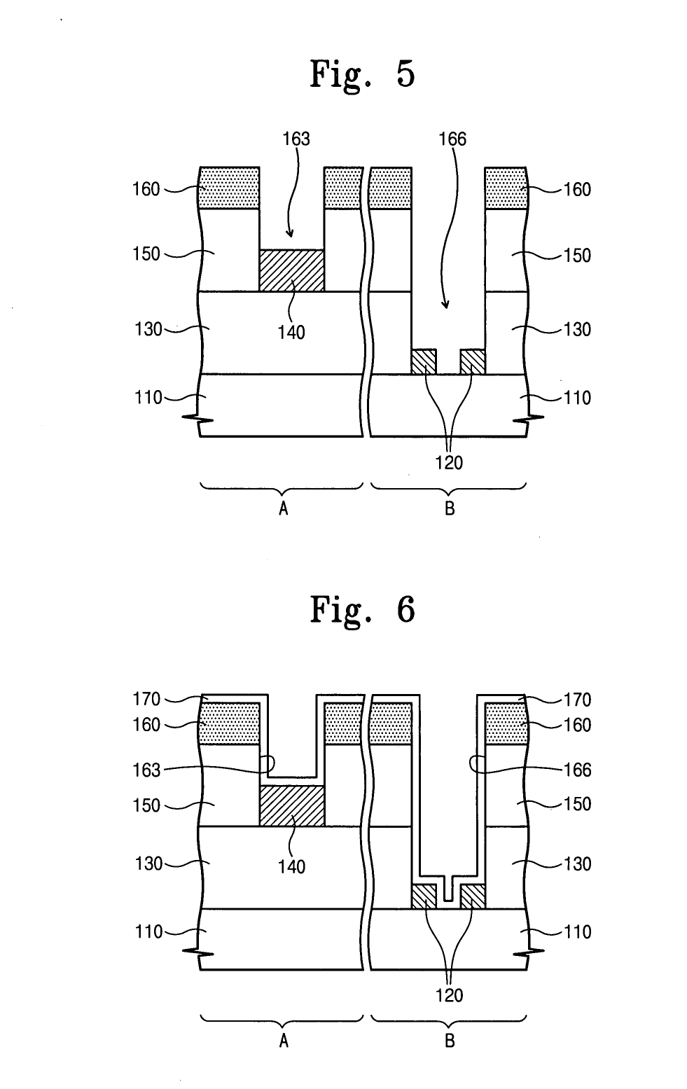

Referring to FIG. 6 and FIG. 9, a thin film forming process may be performed to form a fuse passivation layer 170 on the substrate (S40). The thin film forming process may include, e.g., a chemical vapor deposition (CVD) process, an atomic layer deposition (ALD) process, etc. The thin film forming process may progress at low temperature. The fuse passivation layer 170 may be formed of, e.g., a silicon oxide layer and/or a silicon nitride layer. The fuse passivation layer 170 may cover sides of the pad opening 163, a surface of the bonding pad 140, sides of the fuse opening 166, at least one surface of the fuse 120, a portion of the substrate 110 and the organic passivation layer 160. The fuse passivation layer 170 may be formed to conform to an upper surface of the substrate 110. Here, “conform” means that a material layer is formed to have a relatively uniform thickness according to a profile of a structure formed on the semiconductor substrate.

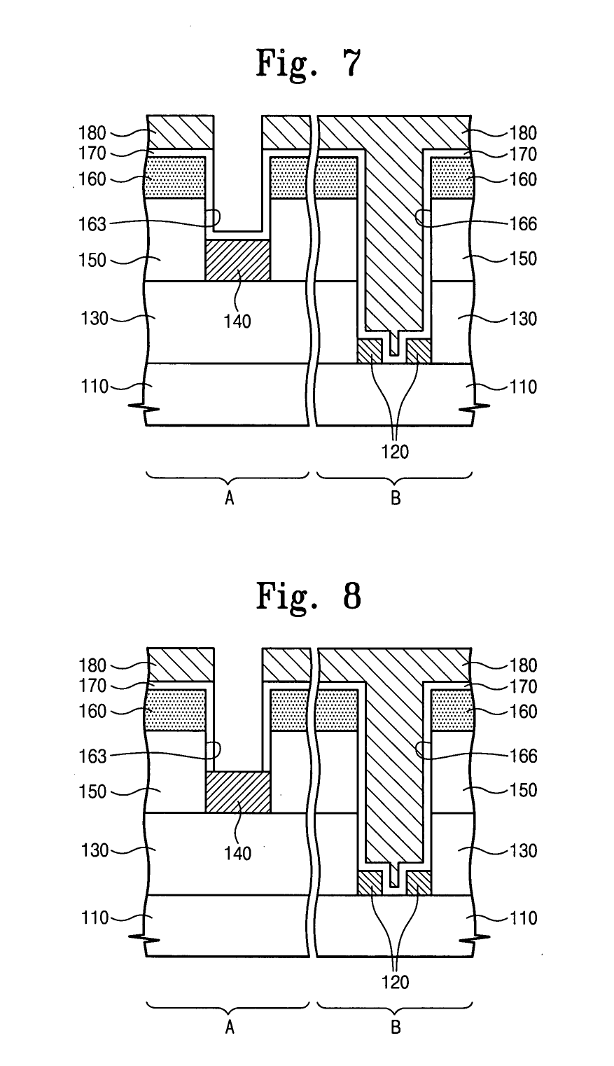

Referring to FIG. 7 and FIG. 9, a photoresist pattern 180 may be formed on the substrate (S50). The photoresist pattern 180 may be formed by light exposure and developing processes after forming a photoresist layer, e.g., a photosensitive organic layer, on the substrate. The fuse passivation layer 170 formed on a bottom surface of the pad opening 163 may be exposed by the photoresist pattern 180.

Referring to FIG. 8 and FIG. 9, an etch process using the photoresist pattern 180 as an etch mask may be performed to pattern the fuse passivation layer 170 and to expose the bonding pad 140 (S60). An anisotropic etch method may be used with, e.g., an etch gas, to selectively etch the fuse passivation layer 170 to expose the bonding pad 140.

Next, by performing an ashing process to remove the photoresist pattern 180, the semiconductor device illustrated in FIG. 2 may be completed.

According to the embodiments of the present invention, a fuse and an organic passivation layer are prevented from outward influence by a fuse passivation layer. Reliability and yield of the semiconductor device may thus be improved.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a semiconductor device, comprising:
forming an interlayer dielectric layer including a bonding pad and a fuse on a semiconductor substrate;
forming an organic passivation layer on a predetermined region of the interlayer dielectric layer;
forming a pad opening and a fuse opening exposing the bonding pad and the fuse by patterning the interlayer dielectric layer by etching using the organic passivation layer as an etch mask;
forming a fuse passivation layer covering the semiconductor substrate; and
patterning the fuse passivation layer to expose the bonding pad.

2. The method of forming the semiconductor device as claimed in claim 1, wherein the fuse passivation layer covers a side surface of the pad opening, and the fuse.

3. The method of forming the semiconductor device as claimed in claim 1, wherein the fuse passivation layer conforms to a profile of the semiconductor substrate.

4. The method of forming the semiconductor device as claimed in claim 1, wherein the fuse passivation layer comprises at least one of a silicon oxide layer or a silicon nitride layer.

5. The method of forming the semiconductor device as claimed in claim 1, wherein the organic passivation layer comprises photosensitive polyimide.

6. A method of forming a semiconductor device, comprising:
forming a first interlayer dielectric layer including a fuse on a semiconductor substrate;
forming a second interlayer dielectric layer including a bonding pad on the first interlayer dielectric layer;
forming an organic passivation layer on a predetermined region of the second interlayer dielectric layer;
forming a pad opening and a fuse opening exposing the bonding pad and the fuse by patterning the first and the second interlayer dielectric layers by etching using the organic passivation layer as an etch mask;
forming a fuse passivation layer covering the organic passivation layer, a side surface and a bottom of the pad opening, and the fuse opening; and
patterning the fuse passivation layer to expose the bonding pad.

7. The method of forming the semiconductor device as claimed in claim 6, wherein the fuse passivation layer conforms to a profile of the semiconductor substrate.

8. The method of forming the semiconductor device as claimed in claim 6, wherein the fuse passivation layer comprises at least one of a silicon oxide layer or a silicon nitride layer.

9. The method of forming the semiconductor device as claimed in claim 6, wherein the organic passivation layer comprises photosensitive polyimide.

10. A semiconductor device, comprising:
an interlayer dielectric layer including a bonding pad and a fuse on a semiconductor substrate, the interlayer dielectric layer having a pad opening and a fuse opening exposing the bonding pad and the fuse, respectively;
an organic passivation layer on the interlayer dielectric layer; and
a fuse passivation layer on the organic passivation layer and exposing the bonding pad.

11. The semiconductor device as claimed in claim 10, wherein the organic passivation layer comprises photosensitive polyimide.

12. The semiconductor device as claimed in claim 10, wherein the fuse passivation layer comprises at least one of a silicon oxide layer or a silicon nitride layer.

13. The semiconductor device as claimed in claim 10, wherein the fuse passivation layer covers a side surface of the pad opening, a side surface of the fuse opening, and a bottom surface of the fuse opening.

14. The semiconductor device as claimed in claim 10, wherein the fuse and the bonding pad comprise aluminum or copper.

15. The semiconductor device as claimed in claim 10, wherein the organic passivation layer shields the semiconductor device from alpha particles.

16. The semiconductor device as claimed in claim 10, wherein the interlayer dielectric layer comprises a first interlayer dielectric layer including the fuse and a second interlayer dielectric layer including the bonding pad.

17. The semiconductor device as claimed in claim 16, wherein the second interlayer dielectric layer comprises a bottom oxide layer and an upper nitride layer, wherein the bottom oxide layer surrounds the bonding pad.

18. The semiconductor device as claimed in claim 16, wherein the first and the second interlayer dielectric layers each comprise at least one material selected from tetraethyl orthosilicate, high density plasma oxide, borophosphosilicate glass, borosilicate glass, or phosphosilicate glass.

19. The semiconductor device as claimed in claim 16, wherein an upper surface of the first interlayer dielectric layer is higher than an upper surface of the fuse.

20. The semiconductor device as claimed in claim 16, wherein an upper surface of the second interlayer dielectric layer is higher than an upper surface of the bonding pad.
